(19) United States
(12) Patent Application Publication
(10) Pub. No.: US 2013/0101818 A1
(43) Pub. Date: Apr. 25, 2013

(54) SURFACE COATING FILM FOR A FORMING MACHINE AND METHOD OF MANUFACTURING THE SAME

(71) Applicants: Sung Chul Cha, Hwaseong (KR); Byung Kyu Cho, Hwaseong (KR); Ho Young Kong, Ulsan (KR); Soo Jin Chung, Seoul (KR); Jun Seok Lee, Incheon (KR)

(72) Inventors: Sung Chul Cha, Hwaseong (KR); Byung Kyu Cho, Hwaseong (KR); Ho Young Kong, Ulsan (KR); Soo Jin Chung, Seoul (KR); Jun Seok Lee, Incheon (KR)

(73) Assignee: HYUNDAI MOTOR COMPANY, Seoul (KR)

(21) Appl. No.: 13/562,998

(22) Filed: Jul. 31, 2012

(30) Foreign Application Priority Data
Oct. 19, 2011 (KR) 10-2011-0106723

(51) Int. Cl. B32B 9/04; C23C 14/35; C23C 16/50; B32B 7/02; B05D 1/36; C23C 16/44

(52) U.S. Cl. 428/213; 427/419.7; 427/255.7; 427/569; 428/697; 427/580

(57) ABSTRACT

Disclosed is a surface coating film for a forming machine, including: a substrate; a nitride layer on the substrate; a multilayered film layer deposited on the nitride layer by reaction of nitrogen (N) with a TiAl target and a Cr target; and a carbonitride layer deposited on the multilayered film layer by reaction of nitrogen (N) and carbon (C) with a TiAl target and a Cr target.

### CROSS-REFERENCE TO RELATED APPLICATIONS

This application claims under 35 U.S.C. §119(a) priority to Korean Application No. 10-2011-0106723, filed on Oct. 19, 2011, the disclosure of which is incorporated herein by reference in its entirety.

### BACKGROUND OF THE INVENTION

1. Technical Field

The present invention relates to a surface coating film for a forming machine and a method of manufacturing the same. In particular, a surface coating film is provided which can improve the physical properties of the forming machine on which it is deposited by use of a multilayered coating layer and a carbon-containing coating layer.

2. Description of the Related Art

With recent increases worldwide in oil prices, and as global warming attributable to climate change has became more serious, various efforts have been made to increase the energy efficiency of automobiles and to improve the travel distance per liter of fuel.

Because of Such efforts include the application of a high-strength high-tension steel sheet to a vehicle body. By applying the high-strength high-tension steel sheet, the weight of a vehicle body can be reduced by about 5˜10% lighter, and it is expected that the travel distance per liter of fuel of the automobile will increase in proportion to the decrease in weight of the vehicle body.

A forming machine, such as a die assembly, is used to form such a high-strength high-tension steel sheet for a vehicle body. In order to increase the formability of a steel sheet by the die assembly, a method of applying various coating layers onto the surface of the die assembly is under development in order to improve the physical properties of the surface of the die assembly. Typical examples of coating materials that have been applied onto a die assembly include TD (Toyota Diffusion), TiAlN, AlTiCrN+MoS₂, etc.

However, such coating materials are problematic in that coating layers formed thereby fall very short in terms of durability and wear resistance. In particular, when such a coating layer is applied for the formation of a high-strength steel sheet of 980 MPa or more, the coating layer strips off and becomes scratched as shown FIG. 1.

In particular, in the case of a conventional TD process, there is a problem in that the coating layer is seriously thermally deformed at the time of heat treatment, and thus the deformed portion of the coating layer must be reformed and prior to use.

Further, when TiAlN or AlTiCrN+MoS₂ is used as a coating material, the durability of the formed coating material is insufficient. Thus, drawing oil is additionally used to reduce friction and abrasion. However, there is a problem in that the drawing oil acts as an impurity during post-processing, such as welding or the like, thus deteriorating the quality of the high-strength steel sheet.

It is to be understood that the foregoing description is provided to merely aid the understanding of the present invention, and does not mean that the present invention falls under the purview of the related art which was already known to those skilled in the art.

### SUMMARY OF THE INVENTION

Accordingly, the present invention has been devised to solve the above-mentioned problems, and an object of the present invention is to provide a surface coating film for a forming machine and a method of manufacturing the same. In particular, a surface coating film is provided which includes a multilayered coating layer and a carbon-containing coating layer, which can improve the physical properties of the forming machine on which it is deposited.

In order to accomplish the above object, an aspect of the present invention provides a surface coating film for a forming machine, including: a substrate; a nitride layer formed on the substrate; a multilayered film layer deposited on the nitride layer; and a carbonitride layer deposited on the multilayered film layer by reaction of nitrogen (N) and carbon (C) with a TiAl target and a Cr target. Preferably, the multilayered film layer is deposited on the nitride layer by reaction of nitrogen (N) with a TiAl target and a Cr target. Further, the carbonitride layer is preferably deposited by reaction of nitrogen (N) and carbon (C) with a TiAl target and a Cr target.

According to various embodiments, the multilayered film layer includes: a CrN layer deposited on the nitride layer; and a TiAlN layer deposited on the CrN layer. According to a preferred embodiment, the CrN layer is deposited by reaction of nitrogen (N) with a Cr target, and the TiAlN layer is deposited by reaction of nitrogen (N) with a TiAl target.

According to various embodiments, multiple CrN layers and TiAlN layers may be provided, such that they are deposited alternately and repeatedly.

According to various embodiments, the CrN layers and the TiAlN layers may be deposited to have nanosized thickness.

According to various embodiments, the thickness of each of the layers may be uniform or may vary. According to various embodiments, the CrN layer deposited on the nitride layer is deposited such that its thickness is greater than the thickness of other CrN layers (i.e. subsequently deposited CrN layers).

According to various embodiments, the carbonitride layer may be a TiAlCN layer, and it may be deposited as the outermost CrN layer of the multilayered film layer.

According to various embodiments, the amount of carbon included in the TiAlCN layer may be about 20˜30 at %.

Another aspect of the present invention provides a method of manufacturing a surface coating film for a forming machine, including the steps of: forming a nitride layer on a substrate; forming a multilayered film layer on the nitride layer=; and forming a carbonitride layer on the multilayered film layer. According to various embodiments, the multilayered film layer is formed by reacting nitrogen (N) with a TiAl target and a Cr target. According to various embodiments, the carbonitride layer is formed by reacting nitrogen (N) and carbon (C) with a TiAl target and a Cr target.

According to various embodiments, the multilayered film layer and the carbonitride layer may be formed by PVD (Physical Vapor Deposition) or PACVD (Plasma-Assisted Chemical Vapor Deposition).

According to various embodiments, the multilayered film layer and the carbonitride layer may be formed by PVD (Physical Vapor Deposition), PACVD (Plasma-Assisted Chemical Vapor Deposition), HIPIMS (High Power Impulse Magnetron Sputtering) or ICP (Inductive Coupled Plasma deposition).

Other aspects and preferred embodiments of the invention are discussed infra.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a damaged area of a conventional die assembly;

FIG. 2 is a schematic view showing the structure of a coating film applied on a substrate according to an embodiment of the present invention;

FIG. 3 is a schematic view showing an apparatus for depositing a coating film according to an embodiment of the present invention;

FIG. 4 is a view showing the structure of a coating film according to an embodiment of the present invention; and

FIG. 5 is a table comparing the coating film of the Example of the present invention with the conventional coating film of the Comparative Example.

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

### DESCRIPTION OF THE PREFERRED EMBODIMENTS

Hereinafter, preferred embodiments of the present invention will be described in detail with reference to the attached drawings.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Ranges provided herein are understood to be shorthand for all of the values within the range. For example, a range of 1 to 50 is understood to include any number, combination of numbers, or sub-range from the group consisting of 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50, as well as all intervening decimal values between the aforementioned integers such as, for example, 1.1, 1.2, 1.3, 1.4, 1.5, 1.6, 1.7, 1.8, and 1.9. With respect to sub-ranges, “nested sub-ranges” that extend from either end point of the range are specifically contemplated. For example, a nested sub-range of an exemplary range of 1 to 50 may comprise 1 to 10, 1 to 20, 1 to 30, and 1 to 40 in one direction, or 50 to 40, 50 to 30, 50 to 20, and 50 to 10 in the other direction.

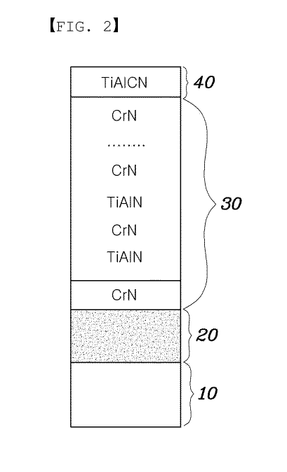

As shown in FIGS. 2 to 5, a surface coating film for a forming machine according to embodiments of the present invention includes: a substrate 10; a nitride layer 20 formed on the substrate 10; a multilayered film layer 30 deposited on the nitride layer 20; and a carbonitride layer 40 deposited on the multilayered film layer 30.

In particular, the multilayered film layer 30 may be deposited on the nitride layer 20 by reaction of nitrogen (N) with a TiAl target and a Cr target.

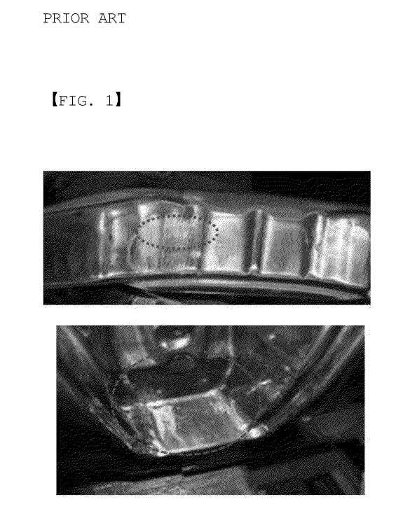

The carbonitride layer 40 may be deposited on the multilayered film layer 30 by reaction of nitrogen (N) and carbon (C) with a TiAl target and a Cr target. That is, the carbonitride layer 40 can be formed on the outermost surface of the substrate 10, as shown in FIG. 1, by adding carbon (C) together with nitrogen (N). The carbonitrite layer 40 on the outermost surface improves the friction coefficient and wear resistance of the substrate 10 coated with the coating film.

According to various embodiments, the carbon (C) may be added using a hydrocarbon gas, such as methane (CH₄), acetylene (C₂H₂), benzene (C₆H₆) or the like. Further, the carbon (C) may also be added using a solid carbon target, such as a graphite target or the like. Meanwhile, the nitrogen (N) may be added using pure nitrogen gas (N₂) or may be added using a nitrogen-containing compound, such as ammonia (NH₃) or the like.

Further, the nitride layer 20 may be formed by any known methods, such as ion nitriding. The ion nitriding is a preferred method because it can be easily performed at low temperature, particularly compared to gas nitriding or salt-bath nitriding. This nitride layer 20 serves to support the coating film on the substrate 10, thus improving the wear resistance, fatigue resistance, impact resistance and corrosion resistance of the coating film.

As shown in FIG. 2, the multilayered film layer 30 may include: a CrN layer deposited on the nitride layer 20; and a TiAlN layer deposited on the CrN layer. The CrN layer may be deposited on the nitride layer 20 by reaction of nitrogen (N) with a Cr target. The TiAlN layer may be deposited on the CrN layer by reaction of nitrogen (N) with a TiAl target.

A plurality of CrN layers and the TiAlN layers may be deposited, for example, alternately and repeatedly in any desired number, as shown in FIG. 2.

Preferably, the CrN layer and the TiAlN layer are deposited to have nanosized thickness.

For example, each of the CrN layers may be deposited to a thickness of about 10˜50 nm, preferably about 25-35 nm, more preferably about 30 nm, and each of the TiAlN layers is deposited to a thickness of about 10-50 nm, preferably about 25-35 nm, more preferably about 30 nm. As shown, the CrN and TiAlN layers can be deposited alternately and repeatedly, to provide the desired heat resistance, cracking resistance, impact resistance, toughness and adhesion. In particular, according to various embodiments, the multilayered film layer 30 has a structure in which several layers having nanosized thickness are laminated, thus further improving the durability of the coating film.

According to a preferred embodiment, the multilayered film layer 30 may have a thickness of about 2˜10 μm. As such, the CrN layers and the TiAlN layers can be provided in any number, and in any thickness(es), uniform or non-uniform, so as to provide the multilayered film layer 30 with the total desired thickness.

According to a preferred embodiment, the CrN layer is deposited on the nitride layer 20 of the present invention such that its thickness is greater than the thickness of other CrN layers.

For example, the CrN layer deposited on the nitride layer 20 may be formed to a thickness of about 0.5˜4 μm, to improve the adhesion between the nitride layer 20 and the TiAlN layer and to enhance the toughness and impact resistance of the coating film.

Meanwhile, as shown in the Figures, the carbonitride layer 40 of the present invention is a TiAlCN layer, and may be formed on the outermost layer, which is preferably a CrN layer, of the multilayered film layer 30. For example, the carbonitride layer 40 may be formed by adding carbon to the TiAlN layer, thus improving the friction coefficient and wear resistance of the substrate 10, as described above.

The amount of carbon included in the TiAlCN layer is preferably about 20˜30 at %. When the amount of carbon is less than 20 at %, the structure of the TiAlCN layer is changed into a crystalline or polycrystalline structure, thus providing the TiAlCN layer with low hardness. Further, when the amount thereof is more than 30 at %, the structure of the TiAlCN layer is changed into an amorphous structure, which also provides the TiAlCN layer with low hardness.

According to embodiments of the present invention, a method of manufacturing a surface coating film for a forming machine includes the steps of: forming a nitride layer 20 on a substrate 10; forming a multilayered film layer 30 on the nitride layer 20, such as by reacting nitrogen (N) with a TiAl target and a Cr target; and forming a carbonitride layer 40 on the multilayered film layer 30, such as by reacting nitrogen (N) and carbon (C) with a TiAl target and a Cr target.

The multilayered film layer 30 and the carbonitride layer 40 may be formed by PVD (Physical Vapor Deposition) or PACVD (Plasma-Assisted Chemical Vapor Deposition).

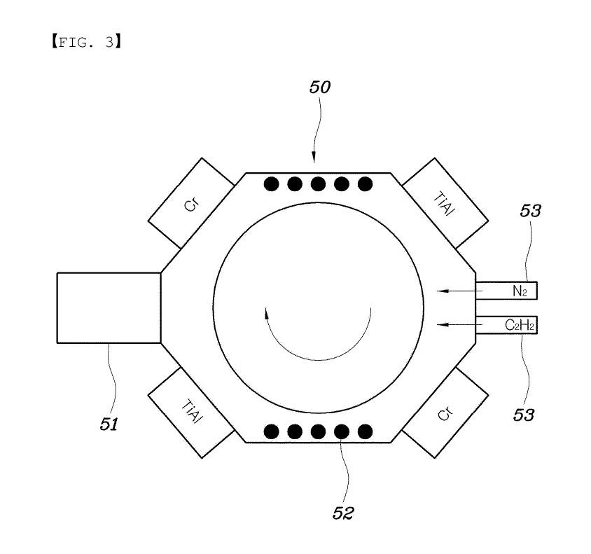

FIG. 3 shows an apparatus for carrying out PVD. In the apparatus, according to an embodiment of the present invention as shown, a pump 51 is provided to control the pressure in a chamber 50, and a heater 52 is provided to increase the temperature in the chamber 50. Further, a substrate 10 is provided at the center of the chamber 50, a TiAl target and a Cr target is provided on the substrate 10 to conduct PVD, and a gas inlet 53 is provided to introduce nitrogen and carbon into the chamber 50.

Further, according to embodiments of the present invention, the multilayered film layer 30 and the carbonitride layer 40 may also be formed by HIPIMS (High Power Impulse Magnetron Sputtering) or ICP (Inductive Coupled Plasma deposition). That is, in order to obtain nanoparticles and realize high-speed coating, HIPIMS (High Power Impulse Magnetron Sputtering) or ICP (Inductive Coupled Plasma deposition) may be additionally used to form the multilayered film layer 30 and the carbonitride layer 40.

Hereinafter, the following Examples are intended to illustrate the present invention without limiting its scope.

### Example

A substrate 10 was made of the same material (SKD11 or the like) as that of a is die assembly used to form a steel sheet for automobiles, and was heat-treated by quenching and/or tempering.

Subsequently, a nitride layer 20 was formed on the substrate 10 by ion nitriding. The ion nitriding was conducted at a temperature of 460˜490 for 8˜15 hours by adding N₂ and H₂ such that the volume ratio of N₂ to H₂ was 15˜20 vol %, thus forming a nitride layer 20 of Fe(N), Fe4N. The nitride layer had a thickness of 80˜120 μm and a hardness of 800˜1200 HV.

Subsequently, a CrN layer was formed on the nitride layer 20 to improve adhesion, toughness and impact resistance, and a TiAlN layer having a thickness of about 30 nm and another CrN layer having a thickness of abut 30 nm were formed on the CrN layer. Then other CrN layers and other TiAlN layers were deposited alternately and repeatedly to provide heat resistance, cracking resistance, impact resistance, toughness and adhesion.

Finally, a TiAlCN layer was deposited on the outermost CrN layer to simultaneously provide low friction, heat resistance, oxidation resistance and wear resistance.

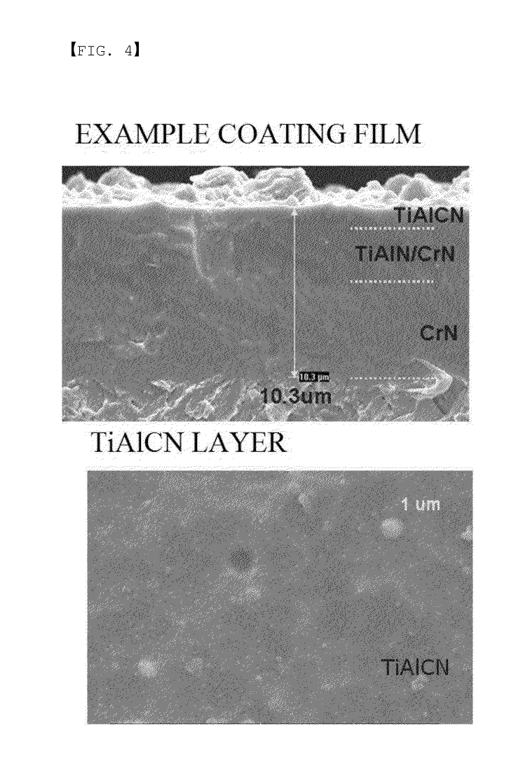

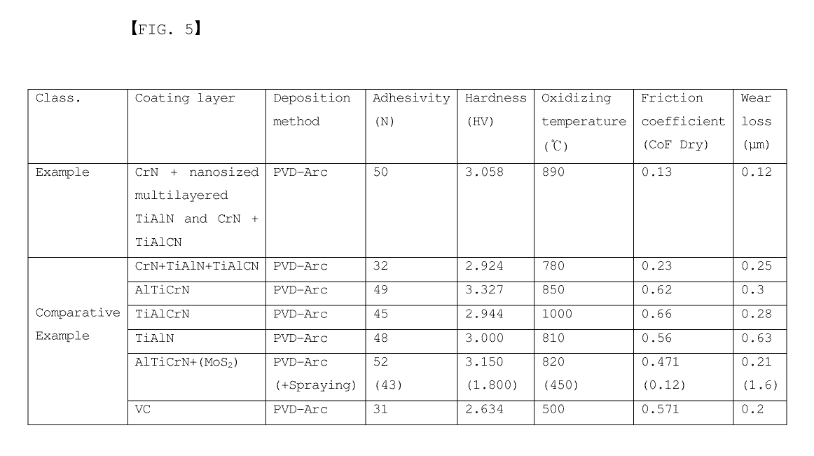

FIG. 4 is a view showing the structure of a coating film according to the Example of the present invention, and FIG. 5 is a table comparing the coating film of the Example of the present invention with the conventional coating film of the Comparative Example. As shown in FIGS. 4 and 5, the die assembly coated with the coating film of the Example of the present invention exhibits high adhesion and hardness, a low friction coefficient and excellent wear resistance compared to the die assembly coated with the conventional coating film of the Comparative Example.

Therefore, the forming machine (die assembly) coated with the coating film of the present invention has a low friction coefficient and improved wear resistance, durability and heat resistance.

As described above, according to the present invention, CrN layers and TiAlN layers having nanosized thickness are alternately deposited on the surface of a forming machine, thus improving heat resistance, cracking resistance and impact resistance. Further, according to the present invention, since a TiAlCN layer containing carbon is deposited on the outermost side of the forming machine, a coating film having excellent heat resistance, wear resistance and durability and a low friction coefficient can be manufactured, thus improving the physical properties of the forming machine which can be used to produce a high-strength steel sheet.

Although the preferred embodiments of the present invention have been disclosed for illustrative purposes, those skilled in the art will appreciate that various modifications, additions and substitutions are possible, without departing from the to scope and spirit of the invention as disclosed in the accompanying claims.

What is claimed is:

1. A surface coating film for a forming machine, comprising:
a substrate;
a nitride layer formed on the substrate;
a multilayered film layer deposited on the nitride layer by reaction of nitrogen (N) with a TiAl target and a Cr target; and
a carbonitride layer deposited on the multilayered film layer by reaction of nitrogen (N) and carbon (C) with a TiAl target and a Cr target.

2. The surface coating film according to claim 1, wherein the multilayered film layer comprises:
a CrN layer deposited on the nitride layer by reaction of nitrogen (N) with a Cr target; and
a TiAlN layer deposited on the CrN layer by reaction of nitrogen (N) with a TiAl target.

3. The surface coating film according to claim 2, wherein the multilayered film layer comprises a plurality of alternating CrN layers and TiAlN layers.

4. The surface coating film according to claim 2, wherein each of the CrN layers and the TiAlN layers have nanosized thickness.

5. The surface coating film according to claim 2, wherein the multilayered film layer comprises a plurality of CrN layers, and wherein the CrN layer deposited on the nitride layer has a thickness is greater than a thickness of other CrN layers.

6. The surface coating film according to claim 1, wherein the carbonitride layer is a TiAlCN layer, and is deposited on an outermost CrN layer of the multilayered film layer.

7. The surface coating film according to claim 6, wherein an amount of carbon included in the TiAlCN layer is about 20˜30 at %.

8. A method of manufacturing a surface coating film for a forming machine, comprising the steps of:
forming a nitride layer on a substrate;
forming a multilayered film layer on the nitride layer by reacting nitrogen (N) with a TiAl target and a Cr target; and
forming a carbonitride layer on the multilayered film layer by reacting nitrogen (N) and carbon (C) with a TiAl target and a Cr target.

9. The method of manufacturing a surface coating film for a forming machine according to claim 8, wherein the multilayered film layer and the carbonitride layer are formed by PVD (Physical Vapor Deposition) or PACVD (Plasma-Assisted Chemical Vapor Deposition).

10. The method of manufacturing a surface coating film for a forming machine according to claim 9, wherein the multilayered film layer and the carbonitride layer are formed by PVD (Physical Vapor Deposition), PACVD (Plasma-Assisted Chemical Vapor Deposition), HIPIMS (High Power Impulse Magnetron Sputtering) or ICP (Inductive Coupled Plasma deposition).
